(19) United States
(12) Patent Application Publication
(10) Pub. No.: US 2022/0043031 A1
(43) Pub. Date: Feb. 10, 2022

(54) METHOD OF ANALYZING A SIGNAL AND SIGNAL ANALYSIS DEVICE

(71) Applicant: Rohde & Schwarz GmbH & Co. KG, Munich (DE)

(72) Inventors: Markus Freidhof, Munich (DE); Philip Diegmann, Munich (DE); Joel Woodward, Munich (DE)

(73) Assignee: Rohde & Schwarz GmbH & Co. KG, Munich (DE)

(21) Appl. No.: 16/987,176

(22) Filed: Aug. 6, 2020

(51) Int. Cl. G01R 13/34; G01R 13/32; G01R 13/24

(52) U.S. Cl. CPC G01R 13/345; G01R 13/24; G01R 13/32

(57) ABSTRACT

A method of analyzing a signal is described. The method includes: setting a trigger condition to be applied; applying the trigger condition; acquiring at least two acquisitions associated with the input signal, each acquisition including a trigger event that matches the trigger condition set; determining a trigger time for each trigger event; storing a time stamp with each trigger event; and generating a histogram based on the time stamps stored, the histogram providing number of trigger events versus time. Further, a signal analysis device for analyzing a signal is described.

### FIELD OF THE DISCLOSURE

The present disclosure relates to a method of analyzing a signal. Moreover, the present disclosure relates to a signal analysis device for analyzing a signal.

### BACKGROUND

In the state of the art, signal analysis devices such as oscilloscopes are known that are used to analyze an input signal received with respect to its characteristics. Modern digital oscilloscopes typically have a large acquisition memory that is used to store digitized samples provided by an analog to digital converter (ADC) connected with an input. Usually, the memory is split into several smaller sections, which are also called segments, wherein each of the several sections is configured to store a respective acquisition. Accordingly, each of the several acquisitions is related to a specific trigger event identified in the input signal or rather the digitized samples obtained from the input signal. For instance, the memory is split into up 1 million segments.

However, it is difficult for an operator of the signal analysis device to navigate through all the acquired segments in order to identify a certain portion of the input signal that has interesting characteristics.

Accordingly, there is a need for a method and signal analysis device that provides the information in an easy accessible manner.

### SUMMARY

The present disclosure provides examples of a method of analyzing a signal. In an embodiment, the method comprises the steps of:

setting a trigger condition to be applied;

applying the trigger condition;

acquiring at least two acquisitions associated with the input signal, each acquisition comprising a trigger event that matches the trigger condition set;

determining a trigger time for each trigger event;

storing a time stamp with each trigger event; and

generating a histogram based on the time stamps stored, the histogram providing number of trigger events versus time.

Furthermore, the present disclosure provides examples of a signal analysis device for analyzing a signal. In an embodiment, the signal analysis device comprises an input, a trigger, such as a trigger circuit or module, an acquisition circuit or module, a timing circuit and a processing circuit or module. The input is configured to receive an input signal to be analyzed by the signal analysis device. The trigger is configured to apply a trigger condition set. The acquisition module is configured to acquire at least two acquisitions associated with the input signal, each acquisition comprising a trigger event that matches the trigger condition set. The timing circuit is configured to determine a trigger time for each trigger event such that a time stamp with each trigger event is stored. The processing module is configured to generate a histogram based on the time stamps stored, wherein the histogram provides number of trigger events versus time.

The main idea is to provide an easy understandable and intuitive overview of the input signal analyzed by the histogram generated. The histogram ensures that the operator is enabled to gather information concerning the input signal analyzed in an easy manner since the number of acquisitions, for example the trigger events, over time is provided by the histogram. In some embodiments, the histogram relates to an overview that can be used by the operator to identify easily when the signal analysis device has triggered an acquisition. Moreover, it can be verified how many or rather how often acquisitions have been triggered in a certain time span since the number of acquisitions or rather trigger events over time is provided by the histogram.

The input signal may be provided by a device under test (DUT) that is probed by a probe that can be connected with the input in order to provide the input signal processed by the signal analysis device. In other words, the signal to be analyzed may relate to a probed signal that is associated with a signal from the device under test.

The number of acquisitions or rather trigger events may be provided in absolute numbers, thereby simply counting the number of events. However, the number of acquisition or rather trigger events may also be provided in relative numbers, for instance ratios.

The histogram relates to an acquisition graph that provides information concerning the temporal characteristics of the input signal with respect to the trigger condition applied. Accordingly, the histogram can be used in signal analysis devices that have a high waveform update rate and/or a deep memory since this typically relates to high number of acquisitions or rather trigger events.

Moreover, the histogram helps to link time information of trigger events with other time information, for instance communication protocol timings of the DUT tested.

In the state of the art, the individual acquisitions are illustrated in a history mode or rather one after the other, resulting in a less intuitive and informative illustration. Moreover, no information concerning the temporal characteristics of the input signal with respect to the trigger condition applied can be provided. Moreover, an overview that takes all or at least several acquisitions into account is not provided.

This however is provided by the histogram. In other words, it is much easier to navigate through a deep memory having several segments, namely a large acquisition memory. In addition, the histogram also provides information between adjacent acquisitions, as information concerning the time between acquisitions is provided by the histogram.

The time stamps may be stored in the same memory in which the acquisitions are stored, namely an acquisition memory. However, the time stamps may also be stored in a separate memory, namely a memory that is different to the acquisition memory.

Furthermore, an analog to digital converter (ADC) may be provided that is directly connected with the input. Hence, an analog signal received via the input may be digitized, thereby generating (digital) samples. Accordingly, the acquisition module may receive (digital) samples that may be stored accordingly.

The trigger may relate to a digital trigger that applies the trigger condition on the digitized samples. Hence, the trigger may interact with a line provided between the analog to digital converter and the acquisition module. Alternatively, the trigger may relate to an analog trigger that applies the trigger condition on the (analog) input signal, for example prior to the digitization of the input signal. Hence, the trigger may interact with a line that directly originates from the input, for example a line provided between the input and the analog to digital converter. Moreover, the trigger may be directly connected with the analog to digital converter.

The input may be connected with the trigger and/or the acquisition module, wherein the trigger and the acquisition module are connected with each other. The input may be directly connected with the analog to digital converter (ADC) such that an analog signal is digitized, thereby providing the (digital) samples. As mentioned above, the trigger may analyze the (digital) samples or rather the (analog) input samples, which depends on the kind of trigger provided.

In the acquisition module, the (digital) samples are typically stored.

The acquisition module may comprise a buffer memory, for instance a ring buffer, in which a certain amount of data, namely samples, is continuously stored for a certain time. When the trigger or trigger module identifies a trigger event, the trigger module controls the acquisition module to permanently store a certain amount of data associated with the trigger event, namely prior to the trigger event (pre-trigger), for instance by accessing the buffer memory, and after the trigger event (post-trigger).

An aspect provides that the histogram is displayed. For instance, the signal analysis device has a display, such as display module, that is connected with the processing module in order to display the histogram. Accordingly, the information provided by the histogram can be illustrated directly such that an operator of the signal analysis device is informed, for example instantly.

Another aspect provides that a certain number of trigger events is grouped within a predetermined bin of the histogram. The trigger events are grouped or rather classified by a certain parameter such that these trigger events are provided collectively. The respective parameter used for grouping may relate to time. Typically, the bin is set by the respective parameter, namely the time, such that the trigger events associated with the parameter, for instance a certain time range, are grouped within one bin. In other words, these trigger events are classified into the same class that is associated with the respective bin.

In some embodiments, the predetermined histogram bin is associated with a predefined time span. The trigger events acquired within the predefined time span are associated with the predetermined histogram bin such that these trigger events are classified commonly.

According to another aspect, the respective bin size is changed by zooming the histogram. The operator is enabled to zoom in or rather zoom out such that the size of the bin, namely the length of the time span, is adapted accordingly.

Therefore, more details can be derived when zooming in since a certain bin having a first size may be split into two or more bins having a reduced size, namely a shorter time span, compared to the initial one that was provided prior to the zoom in.

Further, a zoom out provides a better overview since at least two bins may be summarized to one bin which is associated with a larger time span compared to the respective time spans associated with the at least two bins provided initially.

Accordingly, the operator of the signal analysis device is enabled to adapt the histogram, for example the illustration of the data provided by the histogram, according to his needs.

Typically, the number of trigger events may be plotted on a vertical axis of the histogram. Since the number of trigger events usually varies over time in a dynamic manner, the number of trigger events is provided on the vertical axis, also called y-axis, in order to provide an intuitive illustration of the information.

The number of trigger events may be plotted in a logarithmic manner. Depending on the number of trigger events, the trigger events may be plotted in a logarithmic manner, namely on a logarithmic scale, in order to provide a better overview. The plotting may be changed to a logarithmic scale automatically, for instance once a certain threshold of trigger events is exceeded. Moreover, the logarithmic scale may be used automatically once a certain ratio has been reached or rather exceeded. The ratio may relate to the highest number of trigger events per bin compared to a mean value of trigger events per bin. Thus, the threshold used for automatic switchover of the scale used for generating the histogram may relate to an absolute number or a relative number. Furthermore, the logarithmic scale may be set manually. Hence, the operator may manually set the scale to be used for plotting the number of trigger events.

For instance, the time is plotted on a horizontal axis of the histogram, also called x-axis. The time may be plotted in a linear manner, thereby providing a typical overview of the temporal behavior of the signal analyzed. This ensures an intuitive illustration.

Another aspect provides that the time is plotted in an absolute manner or in a relative manner with respect to a trigger event. The absolute plotting relates to the linear illustration of the time since each pixel of the illustration is associated with a defined time length, which however depends on the zoom level provided. Typically, a good overview of the overall signal is ensued when plotting the time absolutely since time segments without any acquisition or rather trigger event are also illustrated. Moreover, the operator has an overview concerning the frequency of the occurrence of the trigger events. In contrast thereto, the relative plotting automatically skips time segments without any trigger event or rather acquisition, thereby providing a more compact overview of the relevant portions of the signal, namely those having trigger events.

The absolute time may relate to the date and the daytime of the respective acquisition or rather trigger event, whereas the relative time may relate to the time difference to the newest acquisition or rather trigger event.

The time stamp may correspond to a time tag that provides an absolute time reference. The time stamp is stored for each trigger event in an absolute manner, thereby ensuring that the trigger events can be compared with each other since the time stamps provided are comparable with each other. The time stamps are directly stored when the trigger event has been detected by the trigger module or rather the respective acquisition is performed by the acquisition module, thereby ensuring that the absolute times stored are reliable.

Hence, the timing circuit may be at least connected with the trigger module and/or the acquisition module such that the timing circuit is configured to obtain the trigger time for each trigger event. The timing circuit may provide the absolute time of the trigger event occurrence. This can be determined by receiving a signal from the trigger module, for example simultaneously with the acquisition module, or rather receiving the signal from the acquisition module when the acquisition module received the respective signal from the trigger module.

Moreover, the timing circuit may be integrated within the trigger module and/or the acquisition module such that the trigger module or rather the acquisition module determine(s) the trigger time for each trigger event.

The time stamp is stored with each trigger event in the memory that also stores the acquisitions or rather a separate one.

Another aspect provides that at least one bin is selected, thereby providing the number of acquisitions associated with the at least one bin selected and/or the time stamp associated with the at least one bin selected. The signal analysis device may have a selection interface or module via which an operator is enabled to select at least one bin, wherein the processing module is configured to determine the number of acquisitions associated with the at least one bin selected via the selection module and/or the time stamp associated with the at least one bin selected via the selection module. Accordingly, the operator is enabled to interact with the histogram provided by selecting one of the bins in order to get more information concerning data associated with the bin selected, for instance the number of acquisitions of the bin selected and/or the time stamp of the bin selected.

The selection module may be established by a separately formed device that can be moved by the operator, for instance a mouse or rather another device, wherein the movement is tracked. A symbol, for instance a cursor, is generated and illustrated within the histogram such that the operator can move the symbol or rather cursor to a respective bin within the histogram by interacting with the selection module, namely moving the selection module. For selecting the respective bin, a clicking operation may be performed in order to select the bin at which the cursor is located in the histogram.

Moreover, the display module may be a touch-sensitive one such that the display module comprises the selection module in an integral manner. In other words, the selection module is integrated within the display module. Hence, the operator can directly interact with the display module on which the histogram is displayed in order to select the respective bin directly by tipping on the graphically illustrated bin.

The signal analysis device can be a real-time signal analysis device that has zero dead time. Generally, a zero blind time signal analysis device or rather a zero dead time signal analysis device does not miss any trigger event in the input signal processed.

The signal analysis device includes but is not limited to an oscilloscope, a signal analyzer or a spectrum analyzer. Oscilloscopes or rather analyzers are typically used to analyze a respective signal.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a signal analysis device according to an embodiment of the disclosure; and

FIG. 2 shows a histogram provided by a method of analyzing a signal according to an embodiment of the disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

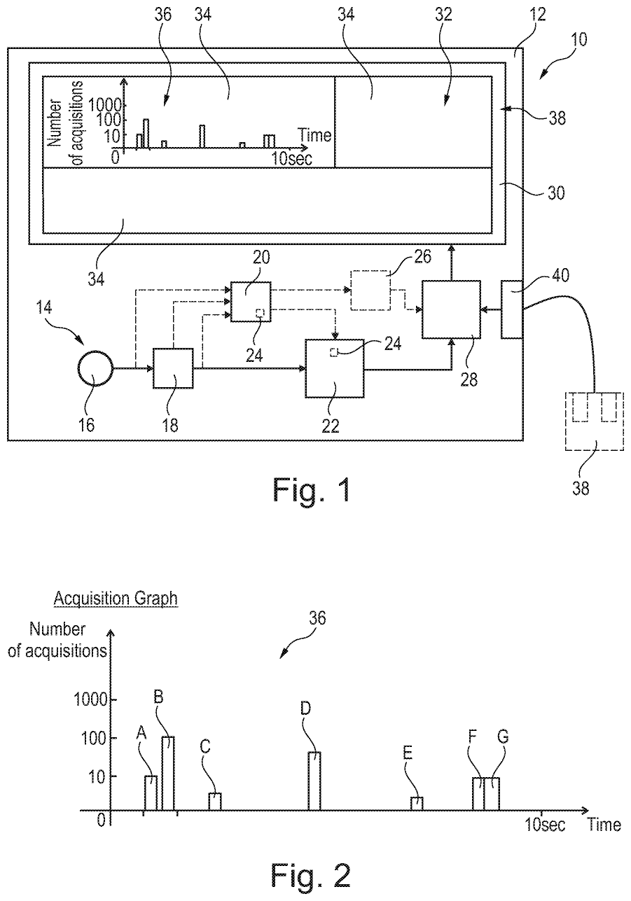

FIG. 1 schematically shows a signal analysis device 10 for analyzing a signal to be analyzed by the signal analysis device 10. The signal analysis device 10 comprises a housing 12 that encompasses internal components of the signal analysis device 10 that are used for processing the signal to be analyzed.

A front end 14 is provided that comprises an input 16 via which an analog signal can be forwarded to the signal analysis device 10, which shall be analyzed by the signal analysis device 10 appropriately. The input signal may be provided by a device under test (not shown) that is probed by a probe, which can be connected with the input 16 in order to provide the input signal. Hence, the signal to be analyzed may relate to a probed signal that is associated with a signal from the device under test. In the shown embodiment, the input 16 is connected with an analog to digital converter 18 (ADC) that digitizes the analog input signal, thereby generating (digital) samples for further processing, namely analyzing purposes.

In addition, the signal analysis device 10 has a trigger, such as a trigger circuit or module 20, that is associated with the input 16 such that a trigger condition can be set via the trigger module 20 and applied on the (analog) input signal or rather the (digital) samples as indicated by the dashed lines in FIG. 1. In some embodiments, the trigger module 20 may also be connected with the analog to digital converter 18.

Furthermore, the signal analysis device 10 comprises an acquisition circuit or module 22. The acquisition module 22 comprises an acquisition memory that is configured to acquire acquisitions associated with the input signal, for instance certain (digital) samples which are derived from the input signal.

Hence, the acquisition module 22 is connected with the input 16, for example via the analog to digital converter 18, as well as the trigger module 20 that applies the trigger condition on the input signal or rather the samples. When the respective trigger condition is met by the input signal or rather the samples, the trigger module 20 triggers the acquisition module 22 to acquire the respective samples associated therewith.

Accordingly, the acquisition module 22 does the respective acquisitions which each comprise a trigger event that matches the trigger condition set and applied by the trigger module 20.

The signal analysis device 10 also includes a timing circuit or unit 24 that may be integrated within the trigger module 20 or the acquisition module 22. Alternatively, the timing unit 24 may be formed separately. In general, the timing unit 24 is configured to determine a trigger time for each trigger event. Accordingly, the trigger module 20 or the acquisition module 22 may determine the respective trigger time.

The trigger time determined is used to provide a time stamp with each trigger event, wherein the respective time stamp is stored in the same memory as the acquisitions, namely within the acquisition module 22, or rather in a separate memory 26 as indicated by the dashed lines in FIG. 1.

The time stamp corresponds to a time tag that provides an absolute time reference of the respective trigger event. Hence, the acquisitions can be compared with each other when referring to the time stamps since they provide an absolute indication concerning the temporal occurrence.

The signal analysis device 10 also comprises a processing circuit or module 28 that is connected with the acquisition module 22 and optionally with the separate memory 26 in case the separate memory 26 is provided.

Accordingly, the processing module 28 is enabled to access the acquisitions as well as the time stamps associated therewith. In some embodiments, the acquisitions as well as the time stamps both are associated with trigger events identified by the trigger module 20 when processing the input signal or rather the samples.

Moreover, the processing module 28 is configured to generate a histogram based on the time stamps stored as well as the acquisitions stored, namely the respective trigger events associated with the acquisitions. In some embodiments, the histogram provides number of trigger events versus time since the number of trigger events identified are illustrated over the time by the histogram.

The respective histogram is rendered or displayed on a display, such as display module 30, that is connected with the processing module 28 such that the histogram generated can be displayed appropriately for informing an operator of the signal analysis device 10.

The processing module 28 and the display module 30 may generally be configured to display a graphical user interface 32 via which the operator is enabled to control the signal analysis device 10 and/or to gather information concerning the signal analyzed. The graphical user interface 32 may provide several areas 34 that can be used to illustrate different content. For instance, the histogram 36 generated is graphically displayed within one of the several areas 34 as illustrated in FIG. 1. The respective histogram provided by the signal analysis device 10 is shown in FIG. 2 in more detail.

In some embodiments, the histogram 36 relates to an acquisition graph, wherein the absolute number of acquisitions or rather trigger events is displayed versus time, thereby providing information concerning the temporal characteristics of the input signal with respect to the trigger condition applied by the trigger module 20.

However, the number of acquisition or rather trigger events may also be provided in relative numbers, for instance ratios.

Generally, a certain number of trigger events acquired is grouped within a predetermined bin of the histogram 36. The trigger events are grouped or rather classified by a certain parameter such that these trigger events are provided collectively within respective bins. Typically, the respective parameter used for grouping relates to time. Hence, the bins are set by the respective parameter, namely the time, such that the trigger events associated with a certain time range are grouped within one bin. In other words, the predetermined histogram bin is associated with a predefined time span, for instance a time span of 1 second or 2 seconds.

In the shown embodiment, several bins A-G of the histogram 36 are shown that have varying numbers of acquisitions or rather trigger events as the respective heights of the bins A-G illustrate.

In the shown embodiment, the number of acquisitions is plotted on the vertical axis, namely the y-axis, whereas the time is plotted on the horizontal axis, namely the x-axis.

In some embodiments, the number of trigger events is plotted in a logarithmic manner, namely on a logarithmic scale, whereas the time may be plotted in a linear manner, namely on a linear scale. The time may be plotted in an absolute manner such that the x-axis can divided into portions with equal length, which relate to equal time spans.

As shown in FIG. 2, information concerning portions of the input signal without trigger event is provided accordingly. Put differently, the histogram 36 also provides information between adjacent acquisitions, as information concerning the time between different acquisitions is provided by the histogram 36 as well.

Alternatively, the time may be plotted in a relative manner with respect to a trigger event such that portions of the input signal without any trigger event can be skipped.

In FIG. 1, it is further shown that a selection module 38 having one or more circuits for generating signals is provided, for instance a mouse, a stylus, one or more switches, or other separately formed input device, that is connected with an interface 40 of the signal analysis device 10.

The operator is enabled to use the selection module 38 in order to select at least one of the several bins A-G illustrated in the histogram 36, thereby causing the processing module 28 to determine the number of acquisitions associated with the bin selected and/or the time stamp associated with the bin selected. In other words, the value associated with the y-axis and/or the value associated with the x-axis are provided accordingly. The respective value(s) may be displayed by the display module 30 in order to inform the operator accordingly.

Alternatively, the display module 30 may be established in a touch-sensitive manner such that the selection module 38 is integrated within the display module 30. Thus, the operator can directly interact with the display module 30 in order to select one of the respective bins A-G in order to retrieve more information concerning the bin selected.

Moreover, the signal analysis device 10 generally provides a zoom functionality such that the operator is enabled to provide a zooming in of the histogram 36 or rather a zooming out of the histogram 36, thereby changing the respective bin size of the bins illustrated.

The zooming in relates to splitting at least one of the several bins into more than one bin since the time span associated with the bins is reduced. For instance, each bin is initially associated with a time span of 2 seconds, wherein a first zoom-in level results in time spans of 1 second associated with each bin.

The zooming out relates to combining several bins initially provided into one bin since the time span associated with the bins is increased. According to an example, each bin is initially associated with a time span of 2 seconds, wherein a first zoom-out level results in time spans of 4 seconds associated with each bin.

Accordingly, the operator of the signal analysis device 10 is enabled to adapt the histogram 36, for example the illustration of the data provided by the histogram 36, according to his needs in order to get a better overview or rather a deeper insight into a certain area of the input signal that is of interest.

In general, the signal analysis device 10 is a real-time signal analysis device that has zero dead time, for example an oscilloscope, a signal analyzer or a spectrum analyzer.

Certain embodiments disclosed herein utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes one or more processors or portions thereof and accompanying software, firmware, hardware, and the like.

In some examples, the functionality described herein can be implemented by special purpose hardware-based computer systems or circuits, etc., or combinations of special purpose hardware and computer instructions.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A method of analyzing a signal, the method comprising:
setting a trigger condition to be applied;
applying the trigger condition;
acquiring at least two acquisitions associated with the input signal, each acquisition comprising a trigger event that matches the trigger condition set;
determining a trigger time for each trigger event;
storing a time stamp with each trigger event; and
generating a histogram based on the time stamps stored, the histogram providing number of trigger events versus time.

2. The method according to claim 1, wherein the histogram is displayed.

3. The method according to claim 1, wherein a certain number of trigger events is grouped within a predetermined bin of the histogram.

4. The method according to claim 3, wherein the predetermined histogram bin is associated with a predefined time span.

5. The method according to claim 1, wherein the respective bin size is changed by zooming the histogram.

6. The method according to claim 1, wherein the number of trigger events is plotted on a vertical axis of the histogram.

7. The method according to claim 1, wherein the number of trigger events is plotted in a logarithmic manner.

8. The method according to claim 1, wherein the time is plotted on a horizontal axis of the histogram.

9. The method according to claim 1, wherein the time is plotted in an absolute manner or in a relative manner with respect to a trigger event.

10. The method according to claim 1, wherein the time stamp corresponds to a time tag that provides an absolute time reference.

11. The method according to claim 1, wherein at least one bin is selected, thereby providing at least one of the number of acquisitions associated with the at least one bin selected and the time stamp associated with the at least one bin selected.

12. A signal analysis device for analyzing a signal, the signal analysis device comprising an input configured to receive an input signal to be analyzed by the signal analysis device;
a trigger configured to apply a trigger condition set;
an acquisition circuit configured to acquire at least two acquisitions associated with the input signal, each acquisition comprising a trigger event that matches the trigger condition set;
a timing circuit configured to determine a trigger time for each trigger event such that a time stamp with each trigger event is stored; and
a processing circuit configured to generate a histogram based on the time stamps stored, wherein the histogram provides number of trigger events versus time.

13. The signal analysis device according to claim 12, wherein the input is connected with at least one of the trigger and the acquisition circuit, and wherein the trigger and the acquisition circuit are connected with each other.

14. The signal analysis device according to claim 12, wherein the timing circuit is at least connected with at least one of the trigger and the acquisition circuit such that the timing circuit is configured to obtain the trigger time for each trigger event.

15. The signal analysis device according to claim 12, wherein the signal analysis device has a display that is connected with the processing circuit in order to display the histogram.

16. The signal analysis device according to claim 12, wherein a selection input is provided via which an operator is enabled to select at least one bin, and wherein the processing circuit is configured to determine at least one of the number of acquisitions associated with the at least one bin selected via the selection input and the time stamp associated with the at least one bin selected via the selection input.

17. The signal analysis device according to claim 12, wherein the signal analysis device is a real-time signal analysis device that has zero dead time.

18. The signal analysis device according to claim 12, wherein the signal analysis device is an oscilloscope, a signal analyzer or a spectrum analyzer.
